(19) United States
(12) Patent Application Publication
(10) Pub. No.: US 2021/0407766 A1
(43) Pub. Date: Dec. 30, 2021

(54) PLASMA PROCESSING APPARATUS

(71) Applicant: Tokyo Electron Limited, Tokyo (JP)

(72) Inventors: Taro IKEDA, Nirasaki City (JP); Toshifumi KITAHARA, Fuchu City (JP); Satoru KAWAKAMI, Narasaki City (JP)

(21) Appl. No.: 17/304,406

(22) Filed: Jun. 21, 2021

(30) Foreign Application Priority Data
Jun. 30, 2020 (JP) 2020-112574

(51) Int. Cl. H01J 37/32

(52) U.S. Cl. CPC H01J 37/3244; H01J 2237/332; H01J 37/32862; H01J 37/32082

(57) ABSTRACT

A plasma processing apparatus includes: a chamber; a substrate support provided within the chamber; a shower head made of a metal and including a plurality of gas holes open toward a space within the chamber, the shower head being provided above the substrate support; a gas supply pipe made of the metal and extending vertically above the chamber to be connected to a center of an upper portion of the shower head; an introduction part formed of a dielectric material and provided along an outer circumference of the shower head so as to introduce electromagnetic waves, which are VHF waves or UHF waves, into the chamber; and an electromagnetic wave supply path connected to the gas supply pipe, wherein the gas supply pipe includes an annular flange, and the supply path includes a conductor connected to the flange.

### CROSS-REFERENCE TO RELATED APPLICATION

This application is based upon and claims the benefit of priority from Japanese Patent Application No. 2020-112574, filed on Jun. 30, 2020, the entire contents of which are incorporated herein by reference.

### TECHNICAL FIELD

An exemplary embodiment of the present disclosure relates to a plasma processing apparatus.

### BACKGROUND

A plasma processing apparatus is used in device manufacturing. Japanese laid-open publication No. 2011-243635 (hereinafter, referred to as “Patent Document 1”) discloses a parallel plate type plasma processing apparatus as a kind of plasma processing apparatus.

The plasma processing apparatus disclosed in Patent Document 1 includes a chamber and an upper electrode. The upper electrode constitutes a shower head. The shower head introduces a film forming gas into the chamber. The upper electrode is connected to a radio-frequency power supply. The radio-frequency power supply supplies radio-frequency power to the upper electrode. The radio-frequency power supplied to the upper electrode generates a radio-frequency electric field inside the chamber. The generated radio-frequency electric field excites the film forming gas inside the chamber to generate plasma. In a film forming process performed on a substrate, chemical species from the plasma are deposited on the substrate to form a film on the substrate.

In addition, the plasma processing apparatus disclosed in Patent Document 1 has a function of cleaning the chamber. Specifically, the plasma processing apparatus disclosed in Patent Document 1 is configured to introduce chemical species such as radicals of a cleaning gas from remote plasma into the chamber from the side wall of the chamber.

### PRIOR ART DOCUMENT

### Patent Document

Patent Document 1: Japanese Laid-Open Patent Publication No. 2011-243635

### SUMMARY

In an exemplary embodiment, a plasma processing apparatus includes: a chamber; a substrate support provided within the chamber; a shower head made of a metal and including a plurality of gas holes open toward a space within the chamber, the shower head being provided above the substrate support; a gas supply pipe made of the metal and extending vertically above the chamber to be connected to a center of an upper portion of the shower head; an introduction part formed of a dielectric material and provided along an outer circumference of the shower head so as to introduce electromagnetic waves, which are very high frequency (VHF) waves or ultra high frequency (UHF) waves, into the chamber; and an electromagnetic wave supply path connected to the gas supply pipe, wherein the gas supply pipe includes an annular flange, and the supply path includes a conductor connected to the flange.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view schematically illustrating a plasma processing apparatus according to an exemplary embodiment.

FIG. 2 is a cross-sectional view taken along line II-II in FIG. 1.

FIG. 3 is a view showing simulation results.

FIG. 4 is a view showing simulation results.

FIG. 5 is a view showing simulation results.

FIG. 6 is a view showing simulation results.

### DETAILED DESCRIPTION

Hereinafter, various exemplary embodiments will be described. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In an exemplary embodiment, a plasma processing apparatus is provided. The plasma processing apparatus includes a chamber, a substrate support, a shower head, a gas supply pipe, an introduction part, and an electromagnetic wave supply path. The substrate support is provided inside the chamber. The shower head is made of a metal. The shower head has a plurality of gas holes, which open toward a space inside the chamber, and is provided above the substrate support. The gas supply pipe is made of a metal. The gas supply pipe extends vertically above the chamber and is connected to the center of an upper portion of the shower head. The introduction part is formed of a dielectric material and is provided along an outer circumference of the shower head so as to introduce electromagnetic waves, which are very high frequency (VHF) waves or ultra high frequency (UHF) waves, into the chamber from the introduction part. The supply path is connected to the gas supply pipe. The gas supply pipe includes an annular flange. The supply path includes a conductor connected to the flange.

In the plasma processing apparatus of the above embodiment, the gas supply pipe is connected to the center of the upper portion of the shower head, and the electromagnetic wave supply path is connected to the flange of the gas supply pipe. Accordingly, the electromagnetic waves propagate uniformly around the gas supply pipe. The electromagnetic waves are introduced into the chamber through the gas supply pipe and the shower head from the introduction part provided along the outer circumference of the shower head. Therefore, according to the plasma processing apparatus of this embodiment, it is possible to improve the uniformity of the density distribution of plasma inside the chamber.

In an exemplary embodiment, the plasma processing apparatus may further include a cover conductor and a dielectric member. The cover conductor has a cylindrical shape and surrounds the gas supply pipe. An upper end of the cover conductor is connected to the gas supply pipe. The dielectric member is provided between a portion of the gas supply pipe in the longitudinal direction and the cover conductor. According to this embodiment, even if the length of the cover conductor in the vertical direction is short and the diameter of the cover conductor is small, it is possible to suppress the occurrence of a higher-order mode.

In an exemplary embodiment, the dielectric member may be provided above the bottom surface of the flange.

In an exemplary embodiment, an area between the bottom surface and the upper end of the flange in a space between the gas supply pipe and the cover conductor may be filled with a dielectric material.

In an exemplary embodiment, a radius R of the flange, a thickness d1 of the flange, and a distance d2 between the bottom surface of the flange and the upper end of the cover conductor may satisfy:

λ_{g}/(4×π)−λ_{g}/(30×π)≤R≤λ_{g}/(4×π),

18 (mm)≤d1≤40 (mm), and

λ_{g}/6≤d2≤λ_{g}/5

where, λ_{g} is the effective wavelength of electromagnetic waves.

In an exemplary embodiment, the plasma processing apparatus may further include a power supply configured to generate the electromagnetic waves.

In an exemplary embodiment, the plasma processing apparatus may further include a first gas source, a second gas source, and a remote plasma source. The first gas source is a gas source configured to supply a film forming gas, and is connected to the gas supply pipe. The second gas source is a gas source configured to supply a cleaning gas. The remote plasma source is connected between the second gas source and the gas supply pipe. The film forming gas may contain a silicon-containing gas. The cleaning gas may contain a halogen-containing gas.

Hereinafter, various exemplary embodiments will be described in detail with reference to the drawings. In each of the drawings, the same or corresponding parts will be denoted by the same reference numerals.

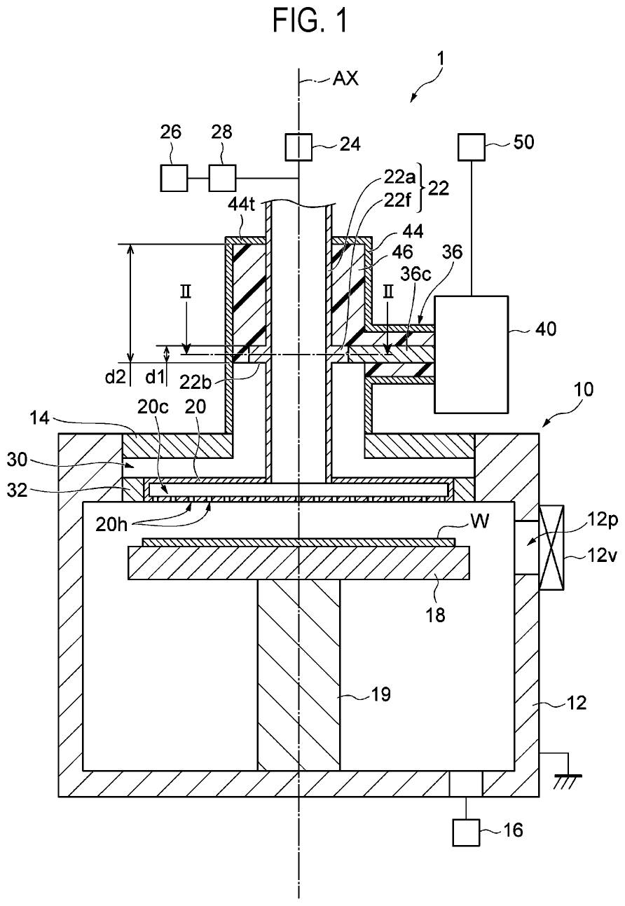

FIG. 1 is a cross-sectional view schematically illustrating a plasma processing apparatus according to an exemplary embodiment. A plasma processing apparatus 1 illustrated in FIG. 1 is a parallel plate type plasma processing apparatus. The plasma processing apparatus 1 is configured to generate plasma by electromagnetic waves. The electromagnetic waves are VHF waves or UHF waves. The VHF wave band is 30 MHz to 300 MHz, and the UHF wave band is 300 MHz to 3 GHz.

The plasma processing apparatus 1 includes a chamber 10. The chamber 10 has an internal space provided therein. A substrate W is processed in the internal space of the chamber 10. The chamber 10 has an axis AX as the central axis thereof. The axis AX is an axis extending in the vertical direction.

In an embodiment, the chamber 10 may include a chamber body 12. The chamber body 12 has a substantially cylindrical shape, and is opened at the upper portion thereof. The chamber body 12 provides the side wall and the bottom of the chamber 10. The chamber body 12 is made of a metal such as aluminum. The chamber body 12 is grounded.

The side wall of the chamber body 12 provides a passage 12p. The substrate W passes through the passage 12p when being transferred between the inside and the outside of the chamber 10. The passage 12p is capable of being opened and closed by a gate valve 12v. The gate valve 12v is provided along the side wall of the chamber body 12.

The chamber 10 may further include an upper wall 14. The upper wall 14 is made of a metal such as aluminum. The upper wall 14 closes the upper opening of the chamber body 12 together with a cover conductor, which will be described later. The upper wall 14 is grounded together with the chamber body 12.

The bottom of the chamber 10 provides an exhaust port. The exhaust port is connected to an exhaust device 16. The exhaust device 16 includes a pressure controller, such as an automatic pressure control valve, and a vacuum pump, such as a turbo molecular pump.

The plasma processing apparatus 1 further includes a substrate support 18. The substrate support 18 is provided inside the chamber 10. The substrate support 18 is configured to support the substrate W placed on the substrate support 18. The substrate W is placed on the substrate support 18 in a substantially horizontal posture. The substrate support 18 may be supported by a support member 19. The support member 19 extends upward from the bottom of the chamber 10. The substrate support 18 and the support member 19 may be formed of a dielectric material such as an aluminum oxide.

The plasma processing apparatus 1 further includes a shower head 20. The shower head 20 is made of a metal such as aluminum. The shower head 20 has a substantially disk shape and may have a hollow structure. The shower head 20 shares the axis AX as the central axis thereof. The shower head 20 is provided above the substrate support 18 and below the upper wall 14. The shower head 20 constitutes a ceiling that defines the internal space of the chamber 10.

The shower head 20 has a plurality of gas holes 20h. The plurality of gas holes 20h are open toward the internal space of the chamber 10. The shower head 20 further provides a gas diffusion chamber 20c therein. The plurality of gas holes 20h are connected to the gas diffusion chamber 20c and extend downward from the gas diffusion chamber 20c.

The plasma processing apparatus 1 further includes a gas supply pipe 22. The gas supply pipe 22 is a cylindrical pipe. The gas supply pipe 22 is made of a metal such as aluminum. The gas supply pipe 22 extends in the vertical direction above the shower head 20. The gas supply pipe 22 shares the axis AX as the central axis thereof. The lower end of the gas supply pipe 22 is connected to the center of the upper portion of the shower head 20. The center of the upper portion of the shower head 20 provides a gas inlet. The gas inlet is connected to the gas diffusion chamber 20c. The gas supply pipe 22 supplies gas to the shower head 20. The gas from the gas supply pipe 22 is introduced into the chamber 10 through the plurality of gas holes 20h via the inlet of the shower head 20 and the gas diffusion chamber 20c.

In an embodiment, the plasma processing apparatus 1 may further include a first gas source 24, a second gas source 26, and a remote plasma source 28. The first gas source 24 is connected to the gas supply pipe 22. The first gas source 24 may be a source of the film forming gas. The film forming gas may contain a silicon-containing gas. The silicon-containing gas contains, for example, SiH4. The film forming gas may further contain other gases. For example, the film forming gas may further contain a NH₃ gas, a N₂ gas, a noble gas such as Ar, and the like. The gas from the first gas source 24 (e.g., the film forming gas) is introduced into the chamber 10 from the shower head 20 via the gas supply pipe 22.

The second gas source 26 is connected to the gas supply pipe 22 via the remote plasma source 28. The second gas source 26 may be a source of a cleaning gas. The cleaning gas may contain a halogen-containing gas. The halogen-containing gas contains, for example, NF3 and/or Cl2. The cleaning gas may further contain other gases. The cleaning gas may further contain a noble gas such as Ar.

The remote plasma source 28 excites the gas from the second gas source 26 at a place separated away from the chamber 10 to generate plasma. In an embodiment, the remote plasma source 28 generates plasma from the cleaning gas. The remote plasma source 28 may be of any type of plasma source. Examples of the remote plasma source 28 may include a capacitively coupled plasma source, an inductively coupled plasma source, and a plasma source configured to generate plasma by microwaves. Radicals in the plasma generated in the remote plasma source 28 are introduced into the chamber 10 from the shower head 20 through the gas supply pipe 22. In order to suppress deactivation of the radicals, the gas supply pipe 22 may have a relatively large diameter. The outer diameter (diameter) of the gas supply pipe 22 is, for example, 40 mm or more. In an example, the outer diameter (diameter) of the gas supply pipe 22 is 80 mm. The outer diameter (diameter) of the gas supply pipe 22 is the outer diameter of the gas supply pipe 22 in another portion 22a of a flange 22f. The flange 22f will be described later.

The shower head 20 is spaced downward from the upper wall 14. A space between the shower head 20 and the upper wall 14 constitutes a portion of a waveguide 30. The waveguide 30 also includes a space provided by the gas supply pipe 22 between the gas supply pipe 22 and the upper wall 14.

The plasma processing apparatus 1 further includes an introduction part 32. The introduction part 32 is formed of a dielectric material such as an aluminum oxide. The introduction part 32 is provided along the outer circumference of the shower head 20 so as to introduce electromagnetic waves into the chamber 10 from the introduction part 32. The introduction part 32 has a ring shape. The introduction part 32 closes a gap between the shower head 20 and the chamber body 12, and is connected to the waveguide 30.

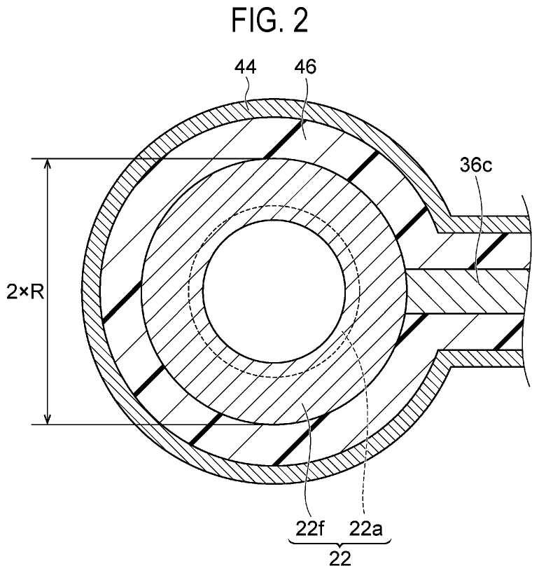

Hereinafter, FIG. 2 together with FIG. 1 will be referred to. FIG. 2 is a cross-sectional view taken along line II-II in FIG. 1. The gas supply pipe 22 described above includes the flange 22f provided annularly in a portion in the longitudinal direction thereof. The flange 22f protrudes radially from the other portion 22a of the gas supply pipe 22.

The plasma processing apparatus 1 further includes an electromagnetic wave supply path 36. The supply path 36 includes a conductor 36c. The conductor 36c of the supply path 36 is connected to the gas supply pipe 22. Specifically, one end of the conductor 36c is connected to the flange 22f.

The plasma processing apparatus 1 may further include a matcher 40 and a power supply 50. The other end of the conductor 36c may be connected to the power supply 50 via the matcher 40. The power supply 50 is an electromagnetic wave generator. The matcher 40 includes an impedance matching circuit. The impedance matching circuit is configured to match the impedance of the load of the power supply 50 with the output impedance of the power supply 50. The impedance matching circuit has a variable impedance. The impedance matching circuit may be, for example, a it-type circuit.

In the plasma processing apparatus 1, electromagnetic waves from the power supply 50 are introduced into the chamber 10 from the introduction part 32 through the matcher 40, the supply path 36 (the conductor 36c), the gas supply pipe 22, and the waveguide 30 around the shower head 20. The electromagnetic waves excite the gas from the first gas source 24 (e.g., the film forming gas) inside the chamber 10 to generate plasma.

In an embodiment, the plasma processing apparatus 1 may further include a cover conductor 44 and a dielectric member 46. The cover conductor 44 has a substantially cylindrical shape. The cover conductor 44 surrounds the gas supply pipe 22 above the chamber 10. The cover conductor 44 is connected to the gas supply pipe 22 at an upper end 44t thereof. That is, the upper end 44t of the cover conductor 44 closes a space between the cover conductor 44 and the gas supply pipe 22. A lower end of the cover conductor 44 is connected to the chamber 10. In an embodiment, the lower end of the cover conductor 44 may be connected to the upper wall 14. The cover conductor 44 may surround the conductor 36c. A space between the cover conductor 44 and the conductor 36c may be filled with a dielectric member. This dielectric member may be integrated with the dielectric member 46.

The dielectric member 46 is formed of a dielectric material. The dielectric member 46 is formed of, for example, polytetrafluoroethylene (PTFE). The dielectric member 46 is provided between a portion of the gas supply pipe 22 in the longitudinal direction and the cover conductor 44. The dielectric member 46 may extend in the radial direction from a portion of the gas supply pipe 22 in the longitudinal direction to an inner surface of the cover conductor 44, and may extend in the circumferential direction to surround the portion of the gas supply pipe 22 in the longitudinal direction. In an embodiment, the dielectric member 46 may be provided above a bottom surface 22b of the flange 22f That is, a position of the lower end of the dielectric member 46 in the vertical direction may be the same as a position of the bottom surface 22b of the flange 22f in the vertical direction. In an embodiment, as illustrated in FIG. 1, an area between the bottom surface 22b of the flange 22f and the upper end 44t of the cover conductor 44 in the space between the gas supply pipe 22 and the cover conductor 44 may be filled with the dielectric member 46.

In an embodiment, a radius R of the flange 22f, a thickness d1 of the flange 22f, and a distance d2 between the bottom surface 22b of the flange 22f and the upper end 44t of the cover conductor 44 may satisfy Equations (1) to (3) below. In addition, λ_{g} is the effective wavelength of electromagnetic waves.

λ_{g}/(4×π)−λ_{g}/(30×π)≤R≤λ_{g}/(4×π) (1)

18 (mm)≤d1≤40 (mm) (2)

λ_{g}/6≤d2≤λ_{g}/5 (3)

When the frequency of electromagnetic wave is 220 MHz and the area between the bottom surface 22b and the upper end 44t in the space between the gas supply pipe 22 and the cover conductor 44 is filled with the dielectric member 46 made of PTFE, Equations (1) and (3) are represented by Equations (1a) and (3a) below.

67 (mm)≤R≤73 (mm) (1a)

158 (mm)≤d2≤183 (mm) (3a)

In the plasma processing apparatus 1 described above, the gas supply pipe 22 is connected to the center of the upper portion of the shower head 20, and the conductor 36c of the electromagnetic wave supply path 36 is connected to the flange 22f of the gas supply pipe 22. Therefore, the electromagnetic waves propagate uniformly around the gas supply pipe 22. The electromagnetic waves are introduced into the chamber 10 from the introduction part 32 provided along the outer circumference of the shower head 20 through the gas supply pipe 22 and the shower head 20. Therefore, according to the plasma processing apparatus 1, it is possible to improve the uniformity of the density distribution of plasma inside the chamber 10.

With the plasma processing apparatus 1, it is possible to remove deposits formed inside the chamber 10 during a film forming process using radicals from the plasma of the cleaning gas. Since the radicals from the plasma of the cleaning gas are supplied through the gas supply pipe 22 and the shower head 20, the deactivation of the plasma is suppressed, and the radicals are uniformly supplied into the chamber 10. Therefore, with the plasma processing apparatus 1, it is possible to uniformly and efficiently clean the chamber 10. In a plasma processing apparatus, which uses VHF waves or UHF waves as electromagnetic waves, it is necessary to supply electromagnetic waves into the chamber through the center of the shower head in order to maintain the density distribution of plasma inside the chamber uniformly. In addition, in order to efficiently and uniformly clean the inside of the chamber, it is necessary to introduce radicals for cleaning from a remote plasma source into the chamber through a relatively thick gas supply pipe connected to the center of the shower head. However, with the structure of the conventional plasma processing apparatus, it is difficult to achieve both the uniformity of plasma density distribution and the uniformity of cleaning. This is because it is difficult to achieve both the introduction of electromagnetic waves into the chamber through the center of the shower head and the introduction of radicals into the chamber through the gas supply pipe connected to the center of the shower head. Meanwhile, with the plasma processing apparatus 1, it is possible to achieve both the improvement of the uniformity of density distribution of plasma in the chamber 10 and the improvement of the uniformity of cleaning inside the chamber 10.

In addition, when the dielectric member 46 is provided, it is possible to suppress the occurrence of a higher-order mode even if the length of the cover conductor 44 in the vertical direction is short and the diameter of the cover conductor 44 is small.

The results of some simulations performed for the evaluation of the plasma processing apparatus 1 will be described below.

First, a first simulation performed as a simulation related to the plasma processing apparatus 1 and a second simulation for comparison will be described. In the first simulation, the distribution of electric field strength inside the chamber 10 when the electromagnetic waves of 220 MHz was introduced into the chamber 10 in the plasma processing apparatus 1 was obtained. The obtained distribution of electric field strength is a distribution in an area spaced apart from the bottom surface of the shower head 20 by 2 mm. The first simulation was performed for a configuration in which the area between the bottom surface 22b of the flange 22f and the upper end 44t of the cover conductor 44 in the space between the gas supply pipe 22 and the cover conductor 44 is filled with the dielectric member 46 made of PTFE. Other conditions in the first simulation are as follows.

### <Conditions of First Simulation>

Outer diameter (diameter) of gas supply pipe 22: 80 mm
Radius R of flange 22f: 69 mm
Thickness d1 of flange 22f: 20 mm
Distance d2 between bottom surface of flange 22f and upper end 44t of cover conductor 44: 163 mm

Conditions of the second simulation were different from the conditions of the first simulation only in that the flange 22f was removed from the gas supply pipe 22.

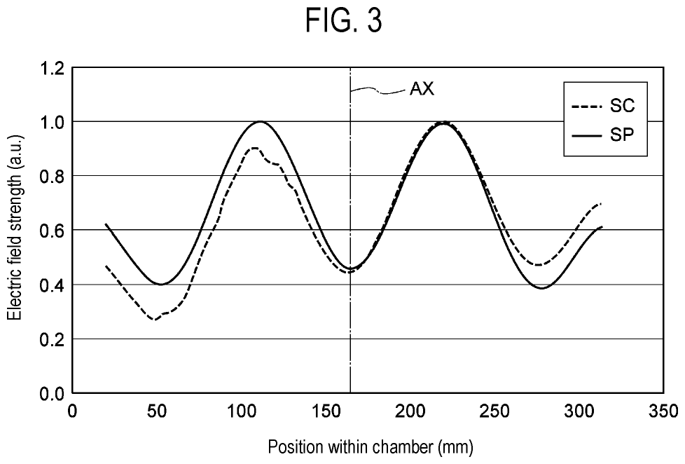

FIG. 3 shows the distributions of electric field strength obtained in the first simulation and the second simulation. In FIG. 3, the horizontal axis indicates a position in the area inside the chamber 10. In FIG. 3, the position of the axis AX is indicated by the dashed-dotted line. The position of the horizontal axis in FIG. 3 is a position on a straight line orthogonal to the axis AX in the area inside the chamber 10. In FIG. 3, the vertical axis represents electric field strength. In FIG. 3, “SP” represents the distribution of electric field strength obtained in the first simulation, and “SC” represents the distribution of electric field strength obtained in the second simulation.

As shown in FIG. 3, in the second simulation, with respect to the axis AX, the symmetry of the distribution of electric field strength on one side and the distribution of electric field strength distribution on the other side was low. That is, it was confirmed that when the flange 22f was removed, the density distribution of plasma generated inside the chamber 10 became non-uniform. Meanwhile, in the first simulation, with respect to the axis AX, the symmetry of the distribution of electric field strength on one side and the distribution of the electric field strength on the other side was high. That is, with the plasma processing apparatus 1 in which electromagnetic waves are supplied through the flange 22f, it was confirmed that the uniformity of the density distribution of plasma generated inside the chamber 10 was high.

Next, a third simulation performed as a simulation related to the plasma processing apparatus 1 will be described. In the third simulation, magnitudes of reflectance coefficients (S11 parameters) when an electromagnetic wave of 220 MHz was introduced into the chamber 10 in the plasma processing apparatus 1 under various conditions for each of the radius R, the thickness d1, and the distance d2 were obtained.

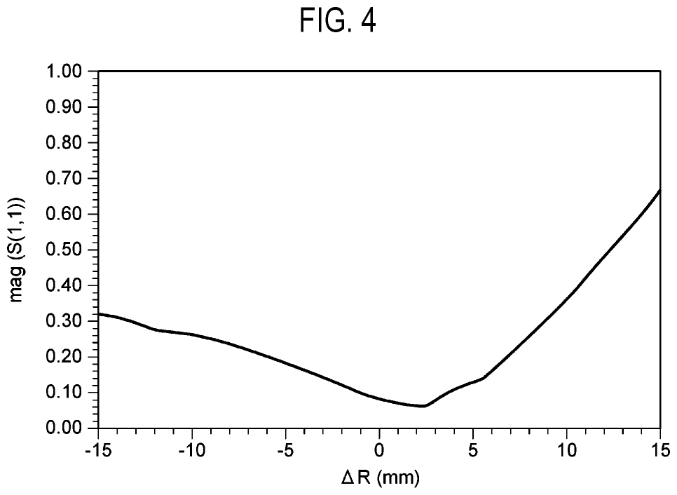

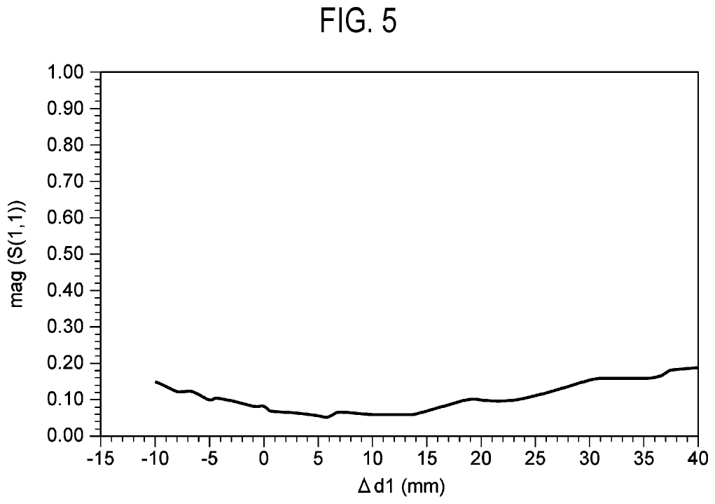

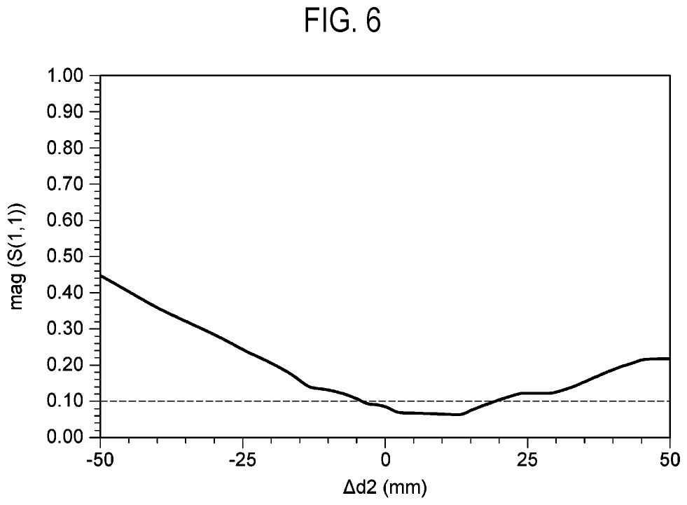

FIGS. 4 to 6 show the magnitudes of the reflectance coefficients obtained in the third simulation. In FIG. 4, ΔR on the horizontal axis is the difference between the value of the radius R in the third simulation and the reference value of 69 mm. In FIG. 5, Δd1 on the horizontal axis is the difference between the value of the thickness d1 in the third simulation and the reference value of 20 mm. In addition, in FIG. 6, Δd2 on the horizontal axis is the difference between the value of the distance d2 in the third simulation and the reference value of 163 mm. In each of FIGS. 4 to 6, mag (S(1,1)) on the vertical axis represents the magnitude of the reflectance coefficient.

As shown in FIG. 4, ΔR satisfying 0.10 or less that is a practically preferable magnitude of the reflectance coefficient was in the range of −2 mm to 4 mm. When ΔR is in the range of −2 mm to 4 mm, the range of the radius R is represented by Equation (1a) above. When Equation (1a) is expressed using the effective wavelength of electromagnetic waves, Equation (1) above is obtained. Therefore, it was confirmed that electromagnetic waves are efficiently used in plasma generation when Equation (1) is satisfied.

In addition, as shown in FIG. 5, Δd1 satisfying that the magnitude of the reflectance coefficient is 0.10 or less was in the range of −2 mm to 20 mm. When Δd1 is in the range of −2 mm to 20 mm, the range of the thickness d1 is represented by Equation (2) above. Therefore, it was confirmed that electromagnetic waves are efficiently used in plasma generation when Equation (2) is satisfied.

Further, as shown in FIG. 6, Δd2 satisfying that the magnitude of the reflectance coefficient is 0.10 or less was in the range of −5 mm to 20 mm. When Δd2 is in the range of −5 mm to 20 mm, the range of the distance d2 is represented by Equation (3a) above. When Equation (3a) is expressed using the effective wavelength of electromagnetic waves, Equation (3) above is obtained. Therefore, it was confirmed that electromagnetic waves are efficiently used in plasma generation when Equation (3) is satisfied.

According to an exemplary embodiment, it is possible to improve the uniformity of a density distribution of plasma generated inside a chamber by electromagnetic waves in a plasma processing apparatus in which a gas supply pipe extends upward from the center of an upper electrode constituting a shower head.

Although various exemplary embodiments have been described above, the present disclosure is not limited to the exemplary embodiments described above, and various omissions, substitutions, and changes may be made. In addition, elements in different embodiments may be combined to form other embodiments.

From the foregoing, it should be understood that various embodiments of the present disclosure have been described herein for purposes of illustration, and that various modifications can be made without departing from the scope and spirit of the present disclosure.

Accordingly, the various embodiments disclosed herein are not intended to be limiting, and the true scope and spirit of the disclosure is indicated by the appended claims.

What is claimed is:

1. A plasma processing apparatus comprising:
a chamber;
a substrate support provided within the chamber;
a shower head made of a metal and including a plurality of gas holes open toward a space within the chamber, the shower head being provided above the substrate support;
a gas supply pipe made of the metal and extending vertically above the chamber to be connected to a center of an upper portion of the shower head;
an introduction part formed of a dielectric material and provided along an outer circumference of the shower head so as to introduce electromagnetic waves, which are very high frequency (VHF) waves or ultra high frequency (UHF) waves, into the chamber; and
an electromagnetic wave supply path connected to the gas supply pipe,
wherein the gas supply pipe includes an annular flange, and
the supply path includes a conductor connected to the flange.

2. The plasma processing apparatus of claim 1, further comprising:
a cover conductor having a cylindrical shape and configured to surround the gas supply pipe, the cover conductor being connected to the gas supply pipe at an upper end thereof; and
a dielectric member provided between a portion of the gas supply pipe in a longitudinal direction and the cover conductor,

3. The plasma processing apparatus of claim 2, wherein the dielectric member is provided above a bottom surface of the flange.

4. The plasma processing apparatus of claim 3, wherein an area between the bottom surface of the flange and the upper end in a space between the gas supply pipe and the cover conductor is filled with the dielectric member.

5. The plasma processing apparatus of claim 4, wherein a radius R of the flange, a thickness d1 of the flange, and a distance d2 between the bottom surface of the flange and the upper end of the cover conductor satisfy:
λ_{g}/(4×π)−λ_{g}/(30×π)≤R≤λ_{g}/(4×π),
18 (mm)≤d1≤40 (mm), and
λ_{g}/6≤d2≤λ_{g}/5,
where λ_{g} is an effective wavelength of the electromagnetic waves.

6. The plasma processing apparatus of claim 5, further comprising:
a power supply configured to generate the electromagnetic waves.

7. The plasma processing apparatus of claim 6, further comprising:
a first gas source connected to the gas supply pipe and configured to supply a film forming gas;
a second gas source configured to supply a cleaning gas; and
a remote plasma source connected between the second gas source and the gas supply pipe.

8. The plasma processing apparatus of claim 7, wherein the film forming gas contains a silicon-containing gas.

9. The plasma processing apparatus of claim 8, wherein the cleaning gas contains a halogen-containing gas.

10. The plasma processing apparatus of claim 1, further comprising:
a power supply configured to generate the electromagnetic waves.

11. The plasma processing apparatus of claim 1, further comprising:
a first gas source connected to the gas supply pipe and configured to supply a film forming gas;
a second gas source configured to supply a cleaning gas; and
a remote plasma source connected between the second gas source and the gas supply pipe.

12. The plasma processing apparatus of claim 2, wherein a radius R of the flange, a thickness d1 of the flange, and a distance d2 between the bottom surface of the flange and the upper end of the cover conductor satisfy:
λ_{g}/(4×π)−λ_{g}/(30×π)≤R≤λ_{g}/(4×π),
18 (mm)≤d1≤40 (mm), and
λ_{g}/6≤d2≤λ_{g}/5,
where λ_{g} is an effective wavelength of the electromagnetic waves.
